(19) United States
(12) Patent Application Publication
(10) Pub. No.: US 2022/0333231 A1
(43) Pub. Date: Oct. 20, 2022

(54) EVAPORATION SOURCE COOLING MECHANISM

(71) Applicant: Applied Materials, Inc., Santa Clara, CA (US)

(72) Inventors: Sambhu KUNDU, Fremont, CA (US); PrasannaKalleshwara Buddappa RAMACHANDRAPPA, Santa Clara, CA (US); Sumedh Dattatraya ACHARYA, Bangalore (IN); Subramanya P. HERLE, Mountain View, CA (US); Nilesh Chimanrao BAGUL, Bangalore (IN); Visweswaren SIVARAMAKRISHNAN, Cupertino, CA (US)

(21) Appl. No.: 17/706,181

(22) Filed: Mar. 28, 2022

Related U.S. Application Data
(60) Provisional application No. 63/175,165, filed on Apr. 15, 2021.

(51) Int. Cl. C23C 14/24; C23C 14/54

(52) U.S. Cl. CPC C23C 14/243; C23C 14/54

(57) ABSTRACT

A method, system, and evaporation source for reactive deposition is provided. The system includes a deposition surface operable for depositing a material onto a substrate provided on the deposition surface. The system further includes an evaporation source positioned for depositing the material onto the substrate. The evaporation source includes a crucible. The crucible includes a base and at least one sidewall extending upward from the base and defining an interior region of the crucible. The evaporation source further includes a cooling mechanism. The cooling mechanism includes a cylindrical cooling jacket surrounding an outer surface of the at least one sidewall while leaving a bottom surface of the base exposed, wherein a cooling gap is defined between the outer surface of the at least one sidewall of the crucible and an inner surface of a sidewall of the cylindrical cooling jacket.

### BACKGROUND

### Field

The present disclosure generally relates to an evaporation system for providing a gas for a reactive deposition process, reactive deposition apparatuses, and methods of reactive deposition. More particularly, the present disclosure generally relates to an evaporation system including a cooling mechanism for rapidly cooling a crucible and methods of rapidly cooling a crucible.

### Description of the Related Art

Processing of flexible substrates, such as plastic films or foils, is in high demand in the packaging industry, semiconductor industries and other industries. Processing may include coating of a flexible substrate with a chosen material, such as a metal. The economical production of these coatings is frequently limited by the thickness uniformity necessary for the product, the reactivity of the coating material, the cost of the coating materials, and the deposition rate of the coating materials. The most demanding applications generally involve deposition occur in a vacuum chamber for precise control of the coating thickness and the optimum optical properties. The high capital cost of vacuum coating equipment necessitates a high throughput of coated area for large-scale commercial applications. The coated area per unit time is typically proportional to the coated substrate width and the vacuum deposition rate of the coating material.

A process that can utilize a large vacuum chamber has tremendous economic advantages. Vacuum coating chambers, substrate treating and handling equipment, and pumping capacity, increase in cost less than linearly with chamber size; therefore, the most economical process for a fixed deposition rate and coating design will utilize the largest substrate available. A larger substrate can generally be fabricated into discrete parts after the coating process is complete. In the case of products manufactured from a continuous web, the web is slit or sheet cut to either a final product dimension or a narrower web suitable for the subsequent manufacturing operations.

One technique used is thermal evaporation. Thermal evaporation readily takes place when a source material is heated in an open crucible within a vacuum chamber when a temperature is reached such that there is a sufficient vapor flux from the source for condensation on a cooler substrate. The source material can be heated indirectly by heating the crucible, or directly by a high current electron beam directed into the source material confined by the crucible. Thermal evaporation typically takes place at high temperatures. Thus, it can be difficult to rapidly cool an evaporation source if needed. One method for cooling an evaporation source is through radiative cooling. However, radiative cooling is typically very slow, which can lead to significant chamber downtime and an increase in cost of ownership.

Thus, there is a need for methods and systems for rapidly cooling evaporation sources.

### SUMMARY

The present disclosure generally relates to an evaporation system for providing a gas for a reactive deposition process, reactive deposition apparatuses, and methods of reactive deposition. More particularly, the present disclosure generally relates to an evaporation system including a cooling mechanism for rapidly cooling a crucible and methods of rapidly cooling a crucible.

In one aspect, an evaporation source is provided. The evaporation source includes a crucible. The crucible includes a base and at least one sidewall extending upward from the base and defining an interior region of the crucible. The evaporation source further includes a cooling mechanism. The cooling mechanism includes a cylindrical cooling jacket surrounding an outer surface of the at least one sidewall while leaving a bottom surface of the base exposed, wherein a cooling gap is defined between the outer surface of the at least one sidewall of the crucible and an inner surface of a sidewall of the cylindrical cooling jacket.

Implementations may include one or more of the following. The evaporation source further includes a plurality of baffles, each baffle extending across the cooling gap from the outer surface of the at least one sidewall to the inner surface of the sidewall of the cylindrical cooling jacket. The cooling gap is from about 1 millimeter to about 4 millimeters. The cooling gap is from about 3 millimeters to about 4 millimeters. The cylindrical cooling jacket has a coolant inlet operable to deliver coolant fluid to the cooling gap and a coolant outlet operable to remove coolant fluid from the cooling gap. The evaporation source further includes a coolant fluid inlet tube fluidly coupled with the coolant inlet and a coolant fluid outlet tube fluidly coupled with the coolant outlet. The coolant fluid is selected from inert gas, clean dry air, and oil. The inert gas is selected from argon and nitrogen. For some processes, which involve reactive gases, argon and nitrogen can be used. For some processes, which involve non-reactive gases, clean dry air can be used. The baffles are spaced from each other to provide uniform flow of the coolant fluid around the outer surface of the at least one sidewall of the crucible. A thermocouple is coupled with the cylindrical cooling jacket and positioned to measure at least one of a temperature of the coolant fluid flowing through the cooling gap and a temperature of the crucible. The cylindrical cooling jacket includes aluminum, stainless steel, molybdenum, alloys thereof, or combinations thereof.

In another aspect, a system for reactive deposition is provided. The system includes a deposition surface operable for depositing a material onto a substrate provided on the deposition surface. The system further includes an evaporation source positioned for depositing the material onto the substrate. The evaporation source includes a crucible. The crucible includes a base and at least one sidewall extending upward from the base and defining an interior region of the crucible. The evaporation source further includes a cooling mechanism. The cooling mechanism includes a cylindrical cooling jacket surrounding an outer surface of the at least one sidewall while leaving a bottom surface of the base exposed, wherein a cooling gap is defined between the outer surface of the at least one sidewall of the crucible and an inner surface of a sidewall of the cylindrical cooling jacket.

Implementations may include one or more of the following. The deposition surface is the surface of a coating drum. The evaporation source further includes a plurality of baffles, each baffle extending across the cooling gap from the outer surface of the at least one sidewall to the inner surface of the sidewall of the cylindrical cooling jacket. The cooling gap is from about 1 millimeter to about 4 millimeters. The cooling gap is from about 3 millimeters to about 4 millimeters. The cylindrical cooling jacket has a coolant inlet operable to deliver coolant fluid to the cooling gap and a coolant outlet operable to remove coolant fluid from the cooling gap. The evaporation source further includes a coolant fluid inlet tube fluidly coupled with the coolant inlet and a coolant fluid outlet tube fluidly coupled with the coolant outlet. The coolant fluid is selected from inert gas, clean dry air, and oil. The inert gas is selected from argon and nitrogen. The baffles are spaced from each other to provide uniform flow of the coolant fluid around the outer surface of the at least one sidewall of the crucible. A thermocouple is coupled with the cylindrical cooling jacket and positioned to measure at least one of a temperature of the coolant fluid flowing through the cooling gap and a temperature of the crucible. The cylindrical cooling jacket includes aluminum, stainless steel, molybdenum, alloys thereof, or combinations thereof.

In yet another aspect, a method of operating an evaporation apparatus is provided. The method includes heating a crucible containing a material to be deposited. The crucible includes a base and at least one sidewall extending upward from the base and defining an interior region of the crucible, the interior region holding the material to be deposited. A cylindrical cooling jacket surrounds an outer surface of the at least one sidewall while leaving a bottom surface of the base exposed, wherein a cooling gap is defined between the outer surface of the at least one sidewall of the crucible and an inner surface of a sidewall of the cylindrical cooling jacket. The method further includes cooling the crucible by flowing a coolant fluid through the cooling gap.

Implementations may include one or more of the following. The cooling gap is from about 1 millimeter to about 4 millimeters. The cooling gap is from about 3 millimeter to about 4 millimeters. The coolant fluid is selected from an inert gas, clean dry air, and oil. The coolant fluid is an inert gas selected from argon and nitrogen. The material to be deposited is a metal or metal alloy.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the implementations, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a schematic side view of an evaporation apparatus having an evaporation source including a cooling mechanism according to one or more implementations of the present disclosure.

FIG. 2 illustrates a schematic cross-section view of one example of an evaporation source including a cooling mechanism according to one or more implementations of the present disclosure.

FIG. 3A illustrates a perspective view of another example of an evaporation source including a cooling mechanism according to one or more implementations of the present disclosure.

FIG. 3B illustrates a cross-sectional view of the evaporation source of FIG. 3A including a cooling mechanism according to one or more implementations of the present disclosure.

FIG. 4 illustrates a flow diagram of a process according to one or more implementations of the present disclosure.

FIG. 5 illustrates a plot of time versus temperature for crucible cooling, which only involves radiative cooling according to a comparative example.

FIG. 6 illustrates a plot of time versus temperature for crucible cooling based on cooling gap size according to one or more implementations of the present disclosure.

FIG. 7 illustrates a plot of time versus temperature for crucible cooling based on varying argon flow rates according to one or more implementations of the present disclosure.

FIG. 8 illustrates a plot of time versus temperature for crucible cooling based on varying pressure in the cooling gap according to one or more implementations of the present disclosure.

FIG. 9 illustrates a plot of time versus temperature for crucible cooling based on varying pressure, flow rate, size of the cooling gap according to one or more implementations of the present disclosure.

FIG. 10 illustrates a plot of time versus temperature for evaporator cooling, without argon flow, according to one or more implementations of the present disclosure.

FIG. 11 illustrates a plot of time versus temperature for evaporator cooling, with argon flow, according to one or more implementations of the present disclosure.

FIG. 12 illustrates a plot of time versus temperature for hot shield cooling, with argon flow, according to one or more implementations of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Reference will now be made in detail to the various implementations of the present disclosure, one or more examples of which are illustrated in the figures. Within the following description of the drawings, the same reference numbers refer to the same components. Generally, only the differences with respect to individual implementations are described. Each example is provided by way of explanation of the present disclosure and is not meant as a limitation of the present disclosure. Further, features illustrated or described as part of one implementation can be used on or in conjunction with other implementations to yield yet a further implementation. It is intended that the description includes such modifications and variations.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

According to some implementations, evaporation processes and evaporation apparatus for layer deposition on substrates, for example on flexible substrates, are provided. Thus, flexible substrates can be considered to include among other things films, foils, webs, strips of plastic material, metal or other materials. Typically, the terms “web,” “foil,” “strip,” “substrate” and the like are used synonymously. According to some implementations, components for evaporation processes, apparatuses for evaporation processes and evaporation processes according to implementations described herein can be provided for the above-described flexible substrates. However, they can also be provided in conjunction with non-flexible substrates such as glass substrates or the like, which are subject to the reactive deposition process from evaporation sources.

Vacuum web coating for anode pre-lithiation and solid metal anode protection involves thick (three to twenty micron) metallic (e.g., lithium) deposition on double-side-coated and calendered alloy-type graphite anodes and current collectors, for example, six micron or thicker copper foil, nickel foil, or metallized plastic web. One technique for deposition is thermal evaporation. Thermal evaporation readily takes place when a source material is heated in an open crucible within a vacuum chamber when a temperature is reached such that there is a sufficient vapor flux from the source for condensation on a cooler substrate. The source material can be heated indirectly by heating the crucible, or directly by a high current electron beam directed into the source material confined by the crucible.

Thermal evaporation typically takes place at high temperatures and it can be difficult to rapidly cool an evaporation source if needed, for example, when the web tears due to high thermal load or condensation energy. One method for cooling an evaporation source is through radiative cooling. However, radiative cooling is typically very slow, which can lead to significant chamber downtime and an increase in cost of ownership. Thus it would be advantageous to have systems and methods for rapidly cooling a crucible after the deposition process is complete.

Implementations of the present disclosure provide an integrated cooling mechanism for a crucible. The integrated cooling mechanism can rapidly cool down the evaporator for example, from a temperature of about 750 degrees Celsius to about 300 degrees Celsius, to reduce unwanted evaporation in the case of a web tear or any other situation where it is desirable to stop the web immediately. The integrated cooling mechanism can be positioned on the outer side of the crucible allowing the crucible to cool down rapidly after the process is completed. The integration of cooling channels on the periphery of the crucible allows cooling options using, for example, clean dray air (CDA), inert gases (e.g., argon), and/or oil for cooling. In particular argon or other inert gas cooling is used when the evaporated metal or metal alloys are reactive under atmospheric condition or if a vacuum leak appears in the system.

Implementations of the present disclosure can include one or more of the following advantages. The rapid cooling provided by the cooling mechanism of present disclosure avoids excessive waste of substrate material. The rapid cooling provided by the cooling mechanism of present disclosure avoids excessive waste of the source material. The rapid cooling provided by the cooling mechanism of present disclosure present disclosure helps prevent a runaway situation in the case or reaction of reactive evaporated material in the presence of oxygen when the evaporator is hot, for example, from about 100 degrees Celsius to about 1,000 degrees Celsius.

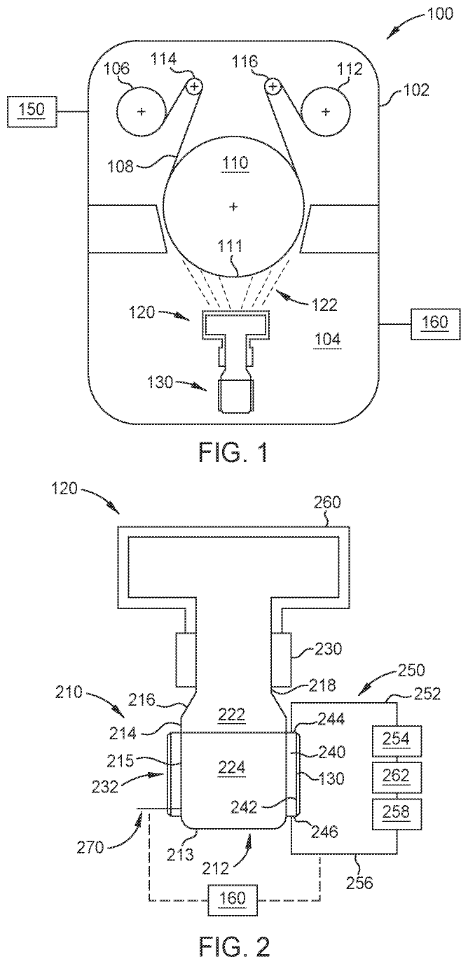

FIG. 1 illustrates a schematic side view of an evaporation system 100 having an evaporation source 120 including a cooling mechanism 130 according to one or more implementations of the present disclosure. The evaporation system 100 can be a SMARTWEB® system, manufactured by Applied Materials, and adapted for manufacturing metal containing film stacks according to the implementations described herein. In one example, the evaporation system 100 can be used for manufacturing lithium-containing anodes, and particularly for film stacks for lithium-containing anodes. The evaporation system 100 includes a chamber body 102 that defines a common processing environment 104 in which some or all of the processing actions for manufacturing lithium-containing anodes can be performed. In one example, the common processing environment 104 is operable as a vacuum environment. In another example, the common processing environment 104 is operable as an inert gas environment. In some examples, the common processing environment 104 can be maintained at a process pressure of 1×10⁻³ mbar or below, for example, 1×10⁻⁴ mbar or below.

The evaporation system 100 is constituted as a reel-to-reel system including an unwinding reel 106 for supplying a continuous flexible substrate 108, a coating drum 110 over which the continuous flexible substrate 108 is processed, and a winding reel 112 for collecting the continuous flexible substrate. The coating drum 110 includes a deposition surface 111 over which the continuous flexible substrate 108 travels while material is deposited onto the continuous flexible substrate 108. The evaporation system 100 can further include one or more auxiliary transfer reels 114, 116 positioned between the unwinding reel 106, the coating drum 110, and the winding reel 112. According to one aspect, at least one of the one or more auxiliary transfer reels 114, 116, the unwinding reel 106, the coating drum 110, and the winding reel 112, can be driven and rotated, by a motor. Although the unwinding reel 106, the coating drum 110, and the winding reel 112 are shown as positioned in the common processing environment 104, it should be understood that the unwinding reel 106 and the winding reel 112 can be positioned in separate chambers or modules, for example, at least one of the unwinding reel 106 can be positioned in an unwinding module, the coating drum 110 can be positioned in a processing module, and the winding reel 112 can be positioned in an unwinding module.

The unwinding reel 106, the coating drum 110, and the winding reel 112 can be individually temperature controlled. For example, the unwinding reel 106, the coating drum 110, and the winding reel 112 can be individually heated using an internal heat source positioned within each reel or an external heat source.

The evaporation system 100 further includes the evaporation source 120 including the cooling mechanism 130. Both the evaporation source 120 and the cooling mechanism will be described in greater detail with reference to FIG. 2. The evaporation source 120 is positioned to perform one processing operation to the continuous flexible substrate 108 or web of material. In one example, as depicted in FIG. 1, the evaporation source 120 is radially disposed about the coating drum 110. In addition, arrangements other than radial are contemplated. In one implementation, the evaporation source is a lithium (Li) source. Further, the evaporation source can also be an alloy of two or more metals. The material to be deposited can be provided in a crucible. The material to be deposited can be evaporated, for example, by thermal evaporation techniques.

In operation, the evaporation source 120 emits a plume of evaporated material 122, which is drawn to the continuous flexible substrate 108 where a film of deposited material is formed on the continuous flexible substrate 108.

In addition, although a single evaporation source, the evaporation source 120 is shown, it should be understood that the evaporation system 100 can further include one or more additional deposition sources. For example, the one or more deposition sources as described herein include an electron beam source and additional sources, which can be selected from the group of CVD sources, PECVD sources, and various PVD sources. Exemplary PVD sources include sputtering sources, electron beam evaporation sources, and thermal evaporation sources.

In some implementations, the evaporation source 120 is positioned in a sub-chamber (not shown). The sub-chamber can isolate the evaporation source 120 from the common processing environment 104. The sub-chamber can include any suitable structure, configuration, arrangement, and/or components that enable the evaporation system 100 to deposit metal containing film stacks according to implementations of the present disclosure. For example, but not limited to, the sub-chambers may include suitable deposition systems including coating sources, power sources, individual pressure controls, deposition control systems, and temperature control. In some implementations, the sub-chamber is provided with individual gas supplies.

In some implementations, the evaporation system 100 is configured to process both sides of the continuous flexible substrate 108. For example, additional evaporation source similar to the evaporation source 120 can be positioned to process the opposing side of the continuous flexible substrate 108. Although the evaporation system 100 is configured to process the continuous flexible substrate 108, which is horizontally oriented, the evaporation system 100 can be configured to process substrates positioned in different orientations, for example, the continuous flexible substrate 108 can be vertically oriented. In some implementations, the continuous flexible substrate 108 is a flexible conductive substrate. In some implementations, the continuous flexible substrate 108 includes a conductive substrate with one or more layers formed thereon. In some implementations, the conductive substrate is a copper substrate.

The evaporation system 100 further includes a gas panel 150. The gas panel 150 uses one or more conduits (not shown) to deliver processing gases to the evaporation system 100. The gas panel 150 can include mass flow controllers and shut-off valves, to control gas pressure and flow rate for each individual gas supplied to the evaporation system 100.

The evaporation system 100 further includes a system controller 160 operable to control various aspects of the evaporation system 100. The system controller 160 facilitates the control and automation of the evaporation system 100 and can include a central processing unit (CPU), memory, and support circuits (or I/O). Software instructions and data can be coded and stored within the memory for instructing the CPU. The system controller 160 can communicate with one or more of the components of evaporation system 100 via, for example, a system bus. A program (or computer instructions) readable by the system controller 160 determines which tasks are performable on a substrate. In some aspects, the program is software readable by the system controller 160, which can include code for monitoring chamber conditions, controlling the evaporation source 120, and the cooling mechanism 130. Although a single system controller, the system controller 160 is shown, it should be appreciated that multiple system controllers can be used with the aspects described herein.

FIG. 2 illustrates a schematic cross-section view of one example of the evaporation source 120 including a cooling mechanism 130 according to one or more implementations of the present disclosure. The evaporation source 120 includes a crucible 210 coupled with the cooling mechanism 130, the cooling mechanism 130 is positioned to rapidly cool the crucible 210. The crucible 210 is fluidly coupled with an evaporator body 260. The evaporator body 260 is operable to deliver evaporated material for deposition. The crucible 210 can be fluidly coupled with the evaporator body 260 via a flange 230. The crucible 210 is removably and adjustably positioned relative to the flange 230. Thus, the crucible 210 can be removed from the evaporator body 260 via the flange 230.

The crucible 210 includes a monolithic restricted orifice vessel capable of holding a deposition material. Referring to FIG. 2, the crucible 210 includes a base 212, a cylindrical body portion 214, a conical portion 216, and a second cylindrical portion 218. The cylindrical body portion 214 includes at least one sidewall 215, which extends upward from the base 212. The base 212 has a bottom surface 213. The base 212 and the cylindrical body portion 214 define an interior region 222. The interior region 222 is operable for holding a material 224 to be deposited. Examples of the material 224 include alkali metals (e.g., lithium and sodium), magnesium, zinc, cadmium, aluminum, gallium, indium, thallium, selenium, tin, lead, antimony, bismuth, tellurium, alkali earth metals, silver, or combinations thereof. In one example, the material includes lithium, selenium, or sodium.

The crucible 210 can be formed of a material having high-thermal conductivity, such as molybdenum, graphite, stainless steel, or boron nitride. In one example, the crucible 210 is composed of pyrolytic boron nitride. Pyrolytic boron nitride is generally inert, can withstand high temperatures, is generally clean and does not contribute undesirable impurities to the vacuum environment, is generally transparent to certain wavelengths of infrared radiation, and can be fabricated into complex shapes, for example.

The evaporation source 120 further includes the cooling mechanism 130. The cooling mechanism 130 is operable to rapidly cool the crucible 210. The cooling mechanism 130 includes a cylindrical cooling jacket 232 or cooling cup. The cylindrical cooling jacket 232 surrounds an outer surface 234 of the at least one sidewall 215 while leaving the bottom surface 213 of the base 212 exposed. The cylindrical cooling jacket 232 can be composed of aluminum, stainless steel, molybdenum, alloys thereof, or combinations thereof.

A cooling gap 240 is defined between the outer surface 234 of the at least one sidewall 215 of the crucible 210 and an inner surface 242 of the cylindrical cooling jacket 232. The cooling gap 240 provides a flow path for coolant fluid to contact the outer surface 234 of the crucible 210 for rapid cooling of the crucible 210. In one example, the cooling gap 240 is from about 1 millimeter to about 6 millimeters. In another example, the cooling gap 240 is from about 1 millimeter to about 4 millimeters. In yet another example, the cooling gap 240 is from about 1 millimeter to about 2 millimeters.

In some implementations, the evaporation source 120 further includes a temperature measurement device 270 positioned to measure the temperature of the coolant fluid flowing through the cooling gap 240. The temperature measurement device can be a non-contact pyrometer or thermocouple.

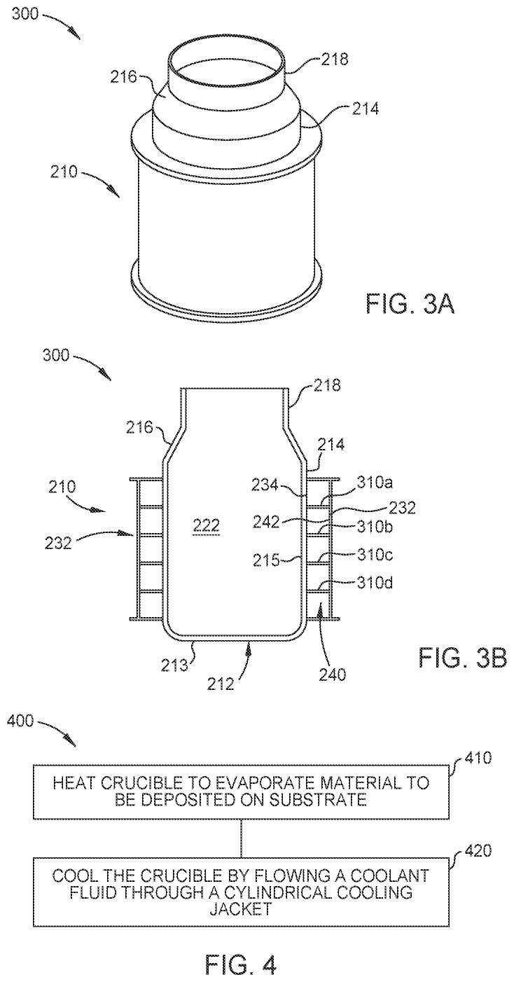

In some implementations, as shown in FIGS. 3A-3B, the cooling mechanism 130 further includes a plurality of baffles 310. Each baffle 310 extends across the cooling gap 240 from the outer surface 234 of the at least one sidewall 215 to the inner surface 242 of the cylindrical cooling jacket 232.

In some implementations, the cylindrical cooling jacket 232 has a coolant inlet 244 operable to deliver coolant fluid to the cooling gap 240. The cylindrical cooling jacket 232 further has a coolant outlet 246 operable to remove coolant fluid from the cooling gap 240. The coolant inlet 244 and the coolant outlet 246 can be fluidly coupled with a cooling loop 250 for supplying coolant fluid to the cooling gap 240. The cooling loop 250 includes a coolant fluid inlet line 252 that fluidly couples a coolant source 254 with the coolant inlet 244. The cooling loop 250 further includes a coolant fluid outlet line 256 fluidly coupled with the coolant outlet 246. The coolant fluid outlet line 256 can be fluidly coupled with a return reservoir 258 for collecting used coolant fluid. The cooling loop 250 can include a heat exchanger 262 for removing heat from the heated coolant fluid prior to returning the coolant to the coolant source 254.

In operation, the coolant fluid can be directed through the coolant fluid inlet line 252 from the coolant source 254 to the cooling gap 240, which traverses the outer surface 234 of the cylindrical body portion 214 of the crucible 210 to remove heat from the crucible 210. The heated cooling liquid can be directed from the cooling gap 240 through the coolant fluid outlet line 256 into the return reservoir 258. The heated cooling liquid may be directed through the heat exchanger 262 to remove heat from the heated cooling liquid prior to returning the coolant to the coolant source 254. It should be understood that the cooling loop 250 depicted in FIG. 2 is only exemplary and that other cooling loop designs can be used. In some examples, the cooling loop 250 has a reservoir which serves both the function of the supply and return reservoirs. In other example, the cooling loop 250 includes the coolant source 254 and the coolant fluid inlet line 252.

In some implementations, the cylindrical cooling jacket 232 is operable to control the temperature of the crucible 210. The cylindrical cooling jacket 232 can surround and be in thermal connection with the crucible 210. In another example, the cylindrical cooling jacket 232 is configured as a double walled cylindrical structure defining a passage or cooling channel between the walls for channeling a heated or cooled liquid. A temperature measurement device 270 can be coupled to at least one of the cylindrical cooling jacket 232 and/or the crucible 210 to provide feedback to a controller, for example, the system controller 160. A flow control mechanism can be provided for changing a flow rate of the heated or cooled liquid through the cylindrical cooling jacket 232 based upon a temperature reading received through feedback from the temperature measurement device 270. Other temperature control sources can be used with the crucible 210. For example, a resistive heater can be thermally coupled or in thermal contact with the crucible 210 for controlling the temperature of the crucible 210.

FIG. 3A illustrates a perspective view of another example of an evaporation source 300 including a cooling mechanism 130 according to one or more implementations of the present disclosure. FIG. 3B illustrates a cross-sectional view of the evaporation source 300 of FIG. 3A including the cooling mechanism 130 according to one or more implementations of the present disclosure. The evaporation source 300 is similar to the evaporation source 120. The evaporation source 300 further includes a plurality of baffles that extend across the cooling gap.

As shown in FIG. 3B, the cooling mechanism 130 further includes a plurality of baffles 310a-310d (collectively 310). Each baffle 310 extends across the cooling gap 240 from the outer surface 234 of the at least one sidewall 215 to the inner surface 242 of the cylindrical cooling jacket 232. The baffles 310 help control the flow rates of the coolant and also provide uniform cooling of the crucible It should be understood that although four baffles are shown, any suitable number of baffles can be used depending upon the chosen coolant flow rates and cooling time for the crucible 210.

FIG. 4 illustrates a process flow chart 400 summarizing one implementation of a method of controlling the temperature of a crucible according to one or more implementations of the present disclosure. The method depicted in the process flow chart 400 can be performed on the evaporation system 100 depicted in FIG. 1 using the evaporation sources 200, 300. At operation 410 a crucible, for example, the crucible 210 is heated to evaporate the material to be deposited on a substrate, for example, the continuous flexible substrate 108. At operation 420, the crucible is cooled by flowing a coolant through a cylindrical cooling jacket, for example, the cylindrical cooling jacket 232.

### Examples

The following non-limiting examples are provided to further illustrate implementations described herein. However, the examples are not intended to be all inclusive and are not intended to limit the scope of the implementations described herein.

In one example during reactive material deposition, a coating drum, for example, the coating drum 110 is maintained at a temperature of 10 degrees Celsius or less, which acts as a heat sink. The evaporator body, for example, evaporator body 260 is maintained at a temperature of about 700 degrees Celsius or higher during processing. And the crucible, for example, crucible 210, is maintained at a temperature of about 700 degrees Celsius or higher during processing and the ambient environment is about 300 degrees Celsius. Various modeling was performed to determine the size the cooling gap, flow rate of the coolant fluid, and pressure within the cooling gap base on cooling the crucible to 150 degrees Celsius in one hour. Some of the hardware and process parameters are depicted in Table I:

TABLE 1

| | | Argon base |
|---|---|---|
| Gap | Flows | pressure |
| 4 mm | 50 SLM | 760 torr |
| 2 mm | 50 SLM | 760 torr |
| 1 mm | 50 SLM | 760 torr |
| 1 mm | 100 SLM | 760 torr |
| 1 mm | 50 SLM | 100 torr |

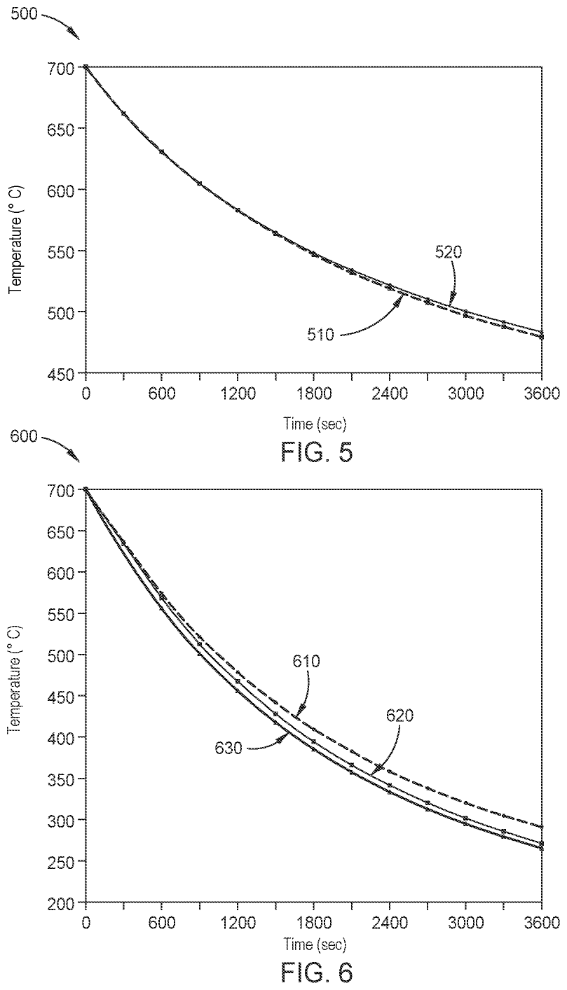

FIG. 5 illustrates a plot 500 of time versus temperature for crucible cooling, which only involves radiative cooling. The cooling curve 510 represents the cooling rate for experimental data and the cooling curve 520 represents the cooling rate for modeling data. The cooling curves 510, 520 depicted in FIG. 5 are based on the assumption of radiative losses only. The evaporator body is radiatively losing heat to the cold coating drum, which is approximately 10 degrees Celsius and the crucible is cooling to the ambient temperature of about 300 degrees Celsius.

FIG. 6 illustrates a plot 600 of time versus temperature for crucible cooling based on cooling gap size according to one or more implementations of the present disclosure. Various cooling gap sizes (1 mm, 2 mm, and 4 mm) were modeled for a cooling gap pressure of 760 torr and an argon flow rate of 50 SLM. The cooling curve 610 represents the cooling rate for a cooling gap of 4 mm. The cooling curve 620 represents the cooling rate for a cooling gap of 2 mm. The cooling curve 630 represents the cooling rate for a cooling gap of 1 mm.

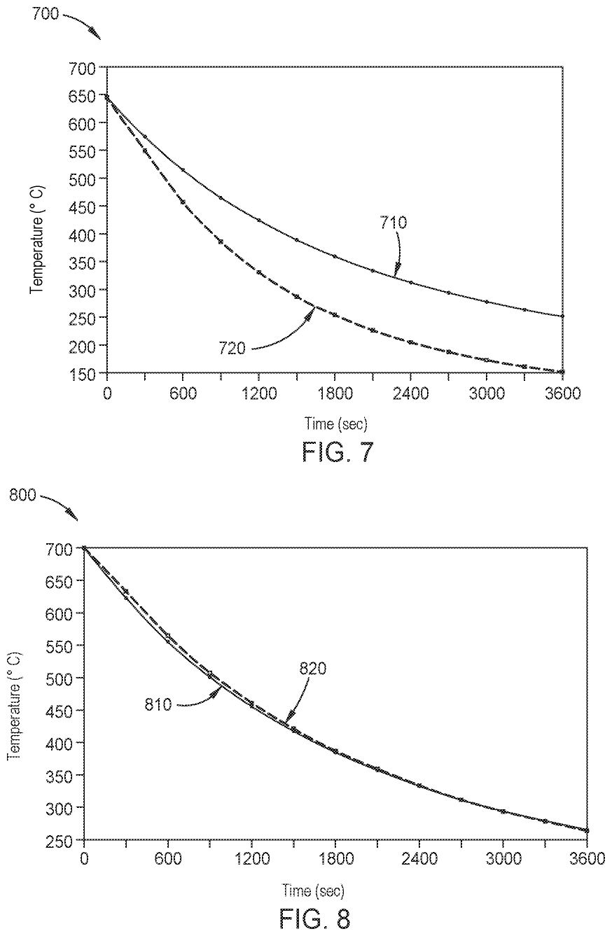

FIG. 7 illustrates a plot 700 of time versus temperature for crucible cooling based on varying argon flow rates according to one or more implementations of the present disclosure. Various argon flow rates (50 SLM and 100 SLM) were modeled for a cooling gap pressure of 760 torr and a cooling gap size of 1 mm. The cooling curve 710 represents the cooling rate for an argon flow rate of 50 SLM. The cooling curve 720 represents the cooling rate an argon flow rate of 100 SLM.

FIG. 8 illustrates a plot 800 of time versus temperature for crucible cooling based on varying pressure in the cooling gap according to one or more implementations of the present disclosure. Various cooling gap pressures (760 torr and 100 torr) were modeled for an argon gas flow rate of 50 SLM and a cooling gap size of 1 mm. The cooling curve 810 represents the cooling rate for a cooling gap pressure of 760 torr. The cooling curve 820 represents a cooling gap pressure of 100 torr.

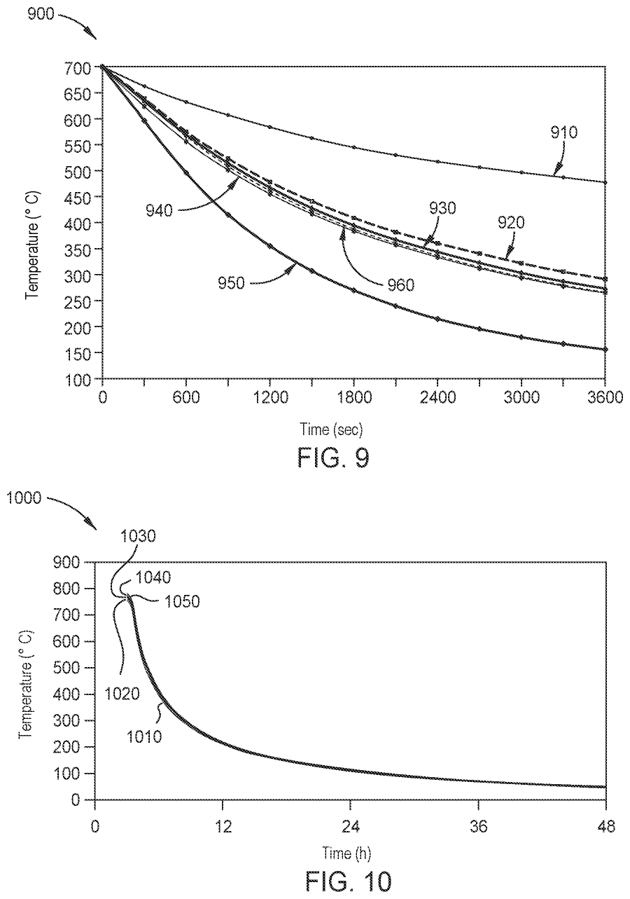

FIG. 9 illustrates a plot 900 of time versus temperature for crucible cooling based on varying pressure, flow rate, size of the cooling gap according to one or more implementations of the present disclosure. Various cooling gap pressures (760 torr and 100 torr), argon flow rates (50 SLM and 100 SLM), and cooling gap size (1 mm, 2 mm, and 4 mm) were modeled. The cooling curve 910 represents the cooling rate for the radiative cooling used in conventional technologies (comparative example). The cooling curve 920 represents the cooling rate for a cooling gap pressure of 760 torr, an argon gas flow rate of 50 SLM, and a cooling gap size of 4 mm. The cooling curve 930 represents the cooling rate for a cooling gap pressure of 760 torr, an argon gas flow rate of 50 SLM, and a cooling gap size of 2 mm. The cooling curve 940 represents the cooling rate for a cooling gap pressure of 760 torr, an argon gas flow rate of 50 SLM, and a cooling gap size of 1 mm. The cooling curve 950 represents the cooling rate for a cooling gap pressure of 760 torr, an argon gas flow rate of 100 SLM, and a cooling gap size of 1 mm. The cooling curve 960 represents the cooling rate for a cooling gap pressure of 100 torr, an argon gas flow rate of 50 SLM, and a cooling gap size of 1 mm.

FIG. 10 illustrates a plot 1000 of time (hours) versus temperature for cooling of the evaporator body, without argon flow, according to one or more implementations of the present disclosure. The cooling rate of the evaporator body was modeled without argon flow. Cooling curves 1010, 1020, 1030, 1040, and 1050 refer to cooling rates for five different thermocouples across the evaporator body. The data indicates that the evaporator body cools from about 775° C. to about 60° C. or less in about 36 hours. The data also indicates that the evaporator body can cool by more than two-thirds (from 775° C. to about 200° C.) in about 12 hours.

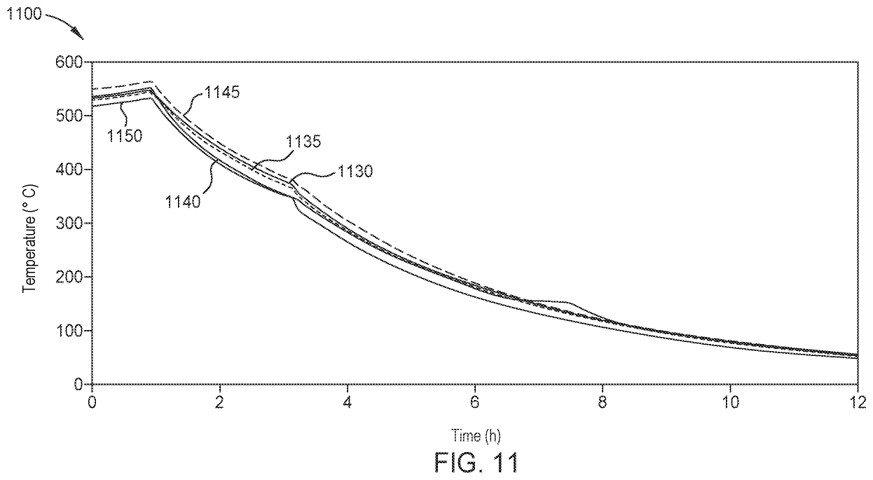

FIG. 11 illustrates a plot 1100 of time (hours) versus temperature for cooling of the evaporator body, with argon flow, according to one or more implementations of the present disclosure. The cooling rate of the evaporator body was modeled for an argon gas flow rate of 100 SLM. Cooling curves 1130, 1135, 1140, 1145, and 1150 represent the cooling rates of the evaporator body using various thermocouples across the evaporator body. The data indicates that various elements of apparatus and systems described herein can cool rapidly.

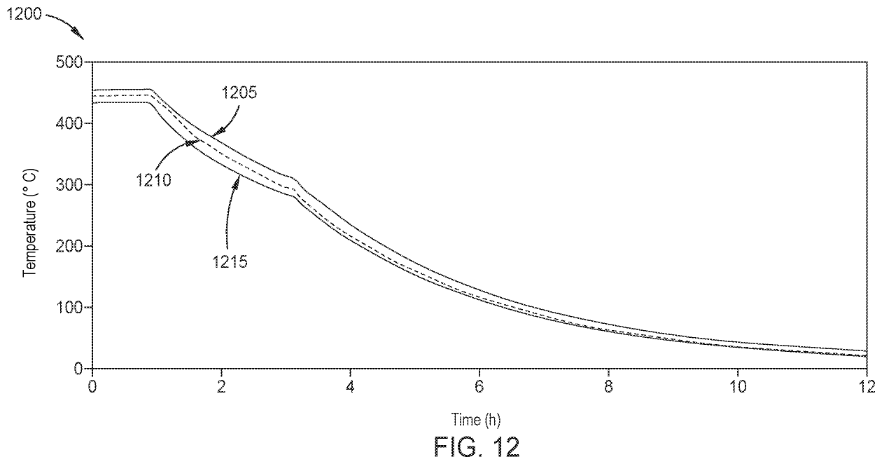

FIG. 12 illustrates a plot 1200 of time (hours) versus temperature for hot shield cooling, with argon flow, according to one or more implementations of the present disclosure. The cooling rates of the hot shield were modeled for an argon gas flow rate of 100 SLM. Cooling curves 1205, 1210, and 1215 represent cooling rates of different zones of the hot shield. Conventional technologies typically require over 48 hours for the hot shield to cool down to temperatures of about 65° C. or less. In contrast, and as shown by the data in FIG. 12, embodiments described herein can enable the hot shield to cool in about 12 hours or less.

### Embodiments Listing

The present disclosure provides, among others, the following aspects, each of which can be considered as optionally including any alternate aspects:

Clause 1. An evaporation source, comprising:
a crucible, comprising:
   a base; and
   at least one sidewall extending upward from the base and defining an interior region of the crucible; and
a cooling mechanism, comprising:
   a cylindrical cooling jacket surrounding an outer surface of the at least one sidewall while leaving a bottom surface of the base exposed, wherein a cooling gap is defined between the outer surface of the at least one sidewall of the crucible and an inner surface of a sidewall of the cylindrical cooling jacket.

Clause 2. The evaporation source of Clause 1, further comprising a plurality of baffles, each baffle extending across the cooling gap from the outer surface of the at least one sidewall to the inner surface of the sidewall of the cylindrical cooling jacket.

Clause 3. The evaporation source of Clause 1 or Clause 2, wherein the cooling gap is from about 1 millimeter to about 4 millimeters.

Clause 4. The evaporation source of any one of Clauses 1-3, wherein the cooling gap is from about 3 millimeters to about 4 millimeters.

Clause 5. The evaporation source of any one of Clauses 1-4, wherein the cylindrical cooling jacket has:

a coolant inlet operable to deliver a coolant fluid to the cooling gap; and

a coolant outlet operable to remove the coolant fluid from the cooling gap.

Clause 6. The evaporation source of Clause 5, further comprising a coolant fluid inlet tube fluidly coupled with the coolant inlet and a coolant fluid outlet tube fluidly coupled with the coolant outlet.

Clause 7. The evaporation source of Clause 5 or Clause 6, wherein the coolant fluid is selected from inert gas, clean dry air, and oil.

Clause 8. The evaporation source of Clause 7, wherein the inert gas is selected from argon and nitrogen.

Clause 9. The evaporation source of any one of Clauses 1-8, wherein the baffles are spaced from each other to provide uniform flow of the coolant fluid around the outer surface of the at least one sidewall of the crucible.

Clause 10. The evaporation source of any one of Clauses 1-9, further comprising a thermocouple coupled with the cylindrical cooling jacket and positioned to measure at least one of a temperature of the coolant fluid flowing through the cooling gap and a temperature of the crucible.

Clause 11. The evaporation source of any one of Clauses 1-10, wherein the cylindrical cooling jacket comprises aluminum, stainless steel, molybdenum, alloys thereof, or combinations thereof.

Clause 12. A system for reactive deposition, comprising:

a deposition surface operable for depositing a material onto a substrate provided on the deposition surface; and

an evaporation source positioned for depositing the material onto the substrate, comprising:
a crucible, comprising:
   a base; and
   at least one sidewall extending upward from the base and defining an interior region of the crucible; and
a cooling mechanism, comprising:
   a cylindrical cooling jacket surrounding an outer surface of the at least one sidewall while leaving a bottom surface of the base exposed, wherein a cooling gap is defined between the outer surface of the at least one sidewall of the crucible and an inner surface of a sidewall of the cylindrical cooling jacket.

Clause 13. The system of Clause 12, wherein the deposition surface is the surface of a coating drum.

Clause 14. The system of Clause 12 or Clause 13, further comprising a plurality of baffles, each baffle extending across the cooling gap from the outer surface of the at least one sidewall to the inner surface of the sidewall of the cylindrical cooling jacket.

Clause 15. The system of any one of Clauses 12-14, wherein the cooling gap is from about 1 millimeter to about 4 millimeters.

Clause 16. The system of any one of Clauses 12-15, wherein the cooling gap is from about 3 millimeters to about 4 millimeters.

Clause 17. The system of any one of Clauses 12-16, wherein the cylindrical cooling jacket has:

a coolant inlet operable to deliver a coolant fluid to the cooling gap; and

a coolant outlet operable to remove the coolant fluid from the cooling gap.

Clause 18. The system of Clause 17, further comprising a coolant fluid inlet tube fluidly coupled with the coolant inlet and a coolant fluid outlet tube fluidly coupled with the coolant outlet.

Clause 19. The system of Clause 17 or Clause 18, wherein the coolant fluid is selected from inert gas, clean dry air, and oil.

Clause 20. The system of any one of Clauses 17-19, wherein the inert gas is selected from argon and nitrogen.

Clause 21. The system of any one of Clauses 12-20, wherein the baffles are spaced from each other to provide uniform flow of the coolant fluid around the outer surface of the at least one sidewall of the crucible.

Clause 22. The system of any one of Clauses 12-21, further comprising a thermocouple coupled with the cylindrical cooling jacket and positioned to measure at least one of a temperature of the coolant fluid flowing through the cooling gap and a temperature of the crucible.

Clause 23. The system of any one of Clauses 12-22, wherein the cylindrical cooling jacket comprises aluminum, stainless steel, molybdenum, alloys thereof, or combinations thereof.

Clause 24. A method of depositing a material on a continuous flexible substrate with a roll-to-roll vapor deposition system according to any one of Clauses 12-23 and/or an evaporation apparatus according to any one of Clauses 1-11.

Clause 25. A method of operating an evaporation apparatus, comprising:

heating a crucible containing a material to be deposited, wherein the crucible comprises:
a base; and
at least one sidewall extending upward from the base and defining an interior region of the crucible, the interior region holding the material to be deposited; and
a cooling mechanism, comprising:
   a cylindrical cooling jacket surrounding an outer surface of the at least one sidewall while leaving a bottom surface of the base exposed, wherein a cooling gap is defined between the outer surface of the at least one sidewall of the crucible and an inner surface of a sidewall of the cylindrical cooling jacket; and

cooling the crucible by flowing a coolant fluid through the cooling gap.

Clause 26. The method of Clause 25, wherein the cooling gap is from about 1 millimeter to about 4 millimeters.

Clause 27. The method of Clause 25 of Clause 26, wherein the cooling gap is from about 3 millimeter to about 4 millimeters.

Clause 28. The method of any one of Clauses 25-27, wherein the coolant fluid is selected from an inert gas, clean dry air, and oil.

Clause 29. The method of any one of Clauses 25-28, wherein the coolant fluid is an inert gas selected from argon and nitrogen.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further implementations of the disclosure may be devised without departing from the basic scope thereof, and the scope thereof is determined by the claims that follow.

1. An evaporation source, comprising:
a crucible, comprising:
a base; and
at least one sidewall extending upward from the base and defining an interior region of the crucible; and
a cooling mechanism, the cooling mechanism comprising a cylindrical cooling jacket surrounding an outer surface of the at least one sidewall while leaving a bottom surface of the base exposed,
wherein a cooling gap is defined between the outer surface of the at least one sidewall of the crucible and an inner surface of a sidewall of the cylindrical cooling jacket.

2. The evaporation source of claim 1, further comprising a plurality of baffles, each baffle extending across the cooling gap from the outer surface of the at least one sidewall to the inner surface of the sidewall of the cylindrical cooling jacket.

3. The evaporation source of claim 2, wherein:
the baffles are spaced from each other to provide uniform flow of a coolant fluid around the outer surface of the at least one sidewall of the crucible;
the cylindrical cooling jacket comprises aluminum, stainless steel, molybdenum, alloys thereof, or combinations thereof; or
combinations thereof.

4. The evaporation source of claim 1, wherein the cooling gap is from about 1 millimeter to about 4 millimeters.

5. The evaporation source of claim 1, wherein the cooling gap is from about 3 millimeters to about 4 millimeters.

6. The evaporation source of claim 1, wherein the cylindrical cooling jacket has:
a coolant inlet operable to deliver a coolant fluid to the cooling gap; and
a coolant outlet operable to remove the coolant fluid from the cooling gap.

7. The evaporation source of claim 6, further comprising a coolant fluid inlet tube fluidly coupled with the coolant inlet and a coolant fluid outlet tube fluidly coupled with the coolant outlet.

8. The evaporation source of claim 6, wherein the coolant fluid is selected from inert gas, clean dry air, oil, or combinations thereof.

9. The evaporation source of claim 1, further comprising a thermocouple coupled with the cylindrical cooling jacket and positioned to measure at least one of a temperature of a coolant fluid flowing through the cooling gap and a temperature of the crucible.

10. A system for reactive deposition, comprising:
a deposition surface operable for depositing a material onto a substrate provided on the deposition surface; and
an evaporation source positioned for depositing the material onto the substrate, comprising:
a crucible, comprising:
a base; and
at least one sidewall extending upward from the base and defining an interior region of the crucible; and
a cooling mechanism comprising a cylindrical cooling jacket surrounding an outer surface of the at least one sidewall while leaving a bottom surface of the base exposed,
wherein a cooling gap is defined between the outer surface of the at least one sidewall of the crucible and an inner surface of a sidewall of the cylindrical cooling jacket.

11. The system of claim 10, wherein the deposition surface is a surface of a coating drum.

12. The system of claim 10, further comprising a plurality of baffles, each baffle extending across the cooling gap from the outer surface of the at least one sidewall to the inner surface of the sidewall of the cylindrical cooling jacket.

13. The system of claim 12, wherein:
the baffles are spaced from each other to provide uniform flow of a coolant fluid around the outer surface of the at least one sidewall of the crucible;
the cylindrical cooling jacket comprises aluminum, stainless steel, molybdenum, alloys thereof, or combinations thereof; or
combinations thereof.

14. The system of claim 10, wherein the cooling gap is from about 1 millimeter to about 4 millimeters.

15. The system of claim 10, wherein the cylindrical cooling jacket has:
a coolant inlet operable to deliver a coolant fluid to the cooling gap; and
a coolant outlet operable to remove the coolant fluid from the cooling gap.

16. The system of claim 15, further comprising a coolant fluid inlet tube fluidly coupled with the coolant inlet and a coolant fluid outlet tube fluidly coupled with the coolant outlet.

17. The system of claim 15, wherein the coolant fluid is selected from argon, nitrogen, clean dry air, and oil.

18. The system of claim 10, further comprising a thermocouple coupled with the cylindrical cooling jacket and positioned to measure at least one of a temperature of a coolant fluid flowing through the cooling gap and a temperature of the crucible.

19. A method of operating an evaporation apparatus, comprising:
heating a crucible containing a material to be deposited, wherein the crucible comprises:
a base;
at least one sidewall extending upward from the base and defining an interior region of the crucible, the interior region holding the material to be deposited; and
a cooling mechanism, comprising:
a cylindrical cooling jacket surrounding an outer surface of the at least one sidewall while leaving a bottom surface of the base exposed, wherein a cooling gap is defined between the outer surface of the at least one sidewall of the crucible and an inner surface of a sidewall of the cylindrical cooling jacket; and
cooling the crucible by flowing a coolant fluid through the cooling gap.

20. The method of claim 19, wherein:
the cooling gap is from about 1 millimeter to about 4 millimeters;
the coolant fluid is selected from an inert gas, clean dry air, and oil;
the material to be deposited is a metal or metal alloy; or
combinations thereof.
